(19) United States
(12) Patent Application Publication
(10) Pub. No.: US 2023/0234471 A1
(43) Pub. Date: Jul. 27, 2023

(54) IN-VEHICLE SYSTEM, BATTERY DIAGNOSTIC METHOD, AND VEHICLE

(71) Applicant: TOYOTA JIDOSHA KABUSHIKI KAISHA, Toyota-shi (JP)

(72) Inventor: Hideaki NAKAMOTO, Chiryu-shi (JP)

(73) Assignee: TOYOTA JIDOSHA KABUSHIKI KAISHA, Toyota-shi (JP)

(21) Appl. No.: 18/154,300

(22) Filed: Jan. 13, 2023

(30) Foreign Application Priority Data
Jan. 25, 2022 (JP) 2022-009664

(51) Int. Cl. B60L 58/14; B60L 58/16

(52) U.S. Cl. CPC B60L 58/14; B60L 58/16; B60L 2260/52

(57) ABSTRACT

An in-vehicle system for diagnosing a battery installed in a vehicle includes a processor. The processor is configured to control the battery to implement sensing discharge, which is discharge processing for sensing deterioration of the battery. The processor is configured to determine whether a result of the sensing discharge satisfies a predetermined condition. The processor performs deterioration determination of the battery when the result of the sensing discharge satisfies the predetermined condition. On the other hand, the processor controls the battery to implement the sensing discharge again when the result of the sensing discharge does not satisfy the predetermined condition.

### CROSS-REFERENCE TO RELATED APPLICATION

This application claims priority to Japanese Patent Application No. 2022-009664 filed on Jan. 25, 2022, incorporated herein by reference in its entirety.

### BACKGROUND

### 1. Technical Field

The present disclosure relates to an in-vehicle system, a battery diagnostic method, and a vehicle.

### 2. Description of Related Art

Japanese Unexamined Patent Application Publication No. 2007-205798 (JP 2007-205798 A) discloses a battery diagnosis device for diagnosing a battery installed in a personal computer. The battery diagnostic device described in JP 2007-205798 A controls various types of devices installed in the personal computer to bring a value of an electric current discharged from the battery to the devices closer to a discharge current value for diagnosis that is set in advance, thereby improving precision of diagnosis of the battery.

### SUMMARY

When a battery installed in a vehicle is being discharged for diagnosis of the battery, there may be cases in which a device such as in-vehicle equipment requests a current that affects the discharge current. There is a problem that in such cases, the discharge current value for battery diagnosis becomes unstable due to the current consumed by the in-vehicle equipment, and accordingly the precision of diagnosis of the battery decreases.

The present disclosure has been made in view of the above problem, and it is an object thereof to provide an in-vehicle system, a battery diagnostic method, and a vehicle, capable of improving precision of diagnosis of a battery.

An in-vehicle system according to a first aspect of the disclosure is an in-vehicle system for diagnosing a battery installed in a vehicle, and the in-vehicle system includes one or more processors. The processors are configured to control the battery to implement sensing discharge, which is discharge processing for sensing deterioration of the battery. Also, the processors are configured to determine whether a result of the sensing discharge satisfies a predetermined condition. The processors are configured to derive an internal resistance value of the battery based on the result of the sensing discharge, and perform deterioration determination of the battery based on the derived internal resistance value, when determination is made that the result of the sensing discharge satisfies the predetermined condition. On the other hand, the processors are configured to control the battery to implement the sensing discharge again when determination is made that the result of the sensing discharge does not satisfy the predetermined condition.

In the in-vehicle system according to the above first aspect, the one or more processors may be configured to control the battery such that the sensing discharge is not implemented until a next trip, when determination is made that the result of the sensing discharge does not satisfy the predetermined condition, and a count of times of the sensing discharge implemented in a current trip of the vehicle reaches a predetermined upper limit count of times.

In the in-vehicle system according to the above first aspect, the one or more processors may be configured to determine that the battery is deteriorated, when determination is made that the result of the sensing discharge does not satisfy the predetermined condition, and the count of times of the sensing discharge implemented in the current trip reaches the predetermined upper limit count of times, and also when a predetermined amount of time or more has elapsed since deterioration determination of the battery was performed a previous time.

In the in-vehicle system according to the above first aspect, the predetermined condition may be that an average value of a discharge current, during implementation of the sensing discharge, is within a predetermined first range.

In the in-vehicle system according to the above first aspect, the predetermined condition may be that a current value, when measuring voltage following implementation of the sensing discharge, is within a predetermined second range.

In the in-vehicle system according to the above first aspect, the processors may be configured to control the battery such that the sensing discharge is implemented in response to a request output by turning on an ignition switch that starts a trip of the vehicle.

In the in-vehicle system according to the first aspect, the one or more processors may be configured to, upon receiving the request, determine whether the battery satisfies a predetermined implementation condition. The predetermined implementation condition here may be a condition such that the battery does not enter an over-discharged state following the sensing discharge.

In the in-vehicle system according to the first aspect, the one or more processors may be configured to determine whether the count of times of the sensing discharge implemented in the current trip has reached a predetermined intermediate count of times. Here, the predetermined intermediate number of times is a fewer count of times than the predetermined upper limit count of times. The processors may be configured to determine whether elapsed time since deterioration determination of the battery was performed a previous time exceeds a predetermined amount of time, when determination is made that the result of the sensing discharge does not satisfy the predetermined condition, and determination is made that the count of times of the sensing discharge implemented in the current trip has reached the predetermined intermediate count of times. The processors may be configured to control the battery to implement the sensing discharge again, when determination is made that the elapsed time exceeds the predetermined amount of time. The processors may be configured to control the battery not to implement the sensing discharge until the next trip, when determination is made that the elapsed time does not exceed the predetermined amount of time.

A battery diagnostic method according to a second aspect of the disclosure is a battery diagnostic method executed by one or more processors of an in-vehicle system for diagnosing a battery installed in a vehicle. The battery diagnostic method includes controlling the battery to implement sensing discharge that is discharge processing for sensing deterioration of the battery, and determining whether a result of the sensing discharge satisfies a predetermined condition. The battery diagnostic method here includes controlling the battery to implement the sensing discharge again when determination is made that the result of the sensing discharge does not satisfy the predetermined condition. The battery diagnostic method includes deriving an internal resistance value of the battery based on the result of the sensing discharge when determination is made that the result of the sensing discharge satisfies the predetermined condition, and performing deterioration determination of the battery based on the internal resistance value.

A vehicle according to a third aspect of the disclosure is a vehicle equipped with the in-vehicle system described above.

According to such a configuration, precision of diagnosis of the battery can be improved.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a functional block diagram of an in-vehicle system according to an embodiment of the present disclosure and peripheral portions thereof;

FIG. 2 is a diagram illustrating an example of paths of electric current released from a second battery in sensing discharge;

FIG. 3A is a flowchart of state determination processing for the second battery, which is performed by the in-vehicle system; and

FIG. 3B is a flowchart of the state determination processing for the second battery, which is performed by the in-vehicle system.

### DETAILED DESCRIPTION OF EMBODIMENTS

An in-vehicle system according to the present disclosure repeatedly implements sensing discharge of a battery. This sensing discharge is repeatedly implemented until desired results are obtained in which highly precise diagnosis of the battery can be performed based on an internal resistance value. On the other hand, in the in-vehicle system according to the present disclosure, when desired results are not obtained even after sensing discharge is performed a predetermined upper limit count of times within a same trip, determination of normal state or determination of abnormal state is made, based on an amount of time elapsed from the previous determination of normal state of the battery, regardless of the internal resistance value of the battery. Thus, precision of diagnosis of the battery is improved.

An embodiment of the present disclosure will be described below in detail with reference to the drawings.

### Embodiment

Configuration

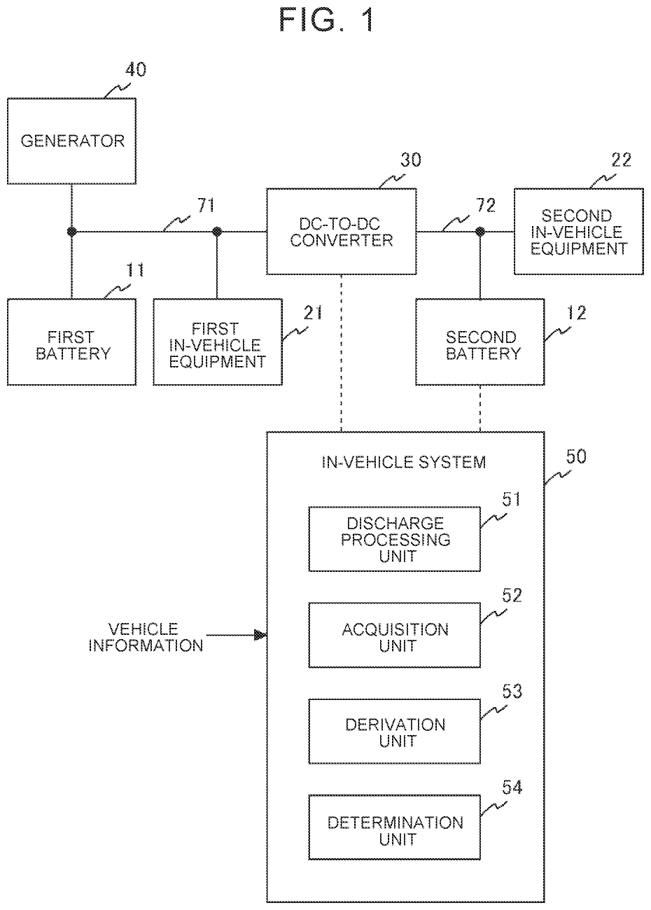

FIG. 1 is a functional block diagram of an in-vehicle system 50 according to an embodiment of the present disclosure, and peripheral portions thereof. The functional blocks exemplified in FIG. 1 include a first battery 11, a second battery 12, first in-vehicle equipment 21, second in-vehicle equipment 22, a direct current (DC)-DC converter 30, a generator 40, and the in-vehicle system 50.

The first battery 11, the first in-vehicle equipment 21, the DC-to-DC converter 30, and the generator 40, are interconnected by a first electric power line 71. The second battery 12, the second in-vehicle equipment 22, and the DC-to-DC converter 30 are interconnected by a second electric power line 72. Also, the second battery 12, the DC-to-DC converter 30, and the in-vehicle system 50 are communicably connected by signal lines (dotted lines in FIG. 1), and control signals, measured values, and the like are exchanged.

The in-vehicle system 50 according to the present embodiment can be installed in a vehicle or the like equipped with an electric power supply system that requires a redundant electric power supply configuration. An example of a vehicle equipped with the electric power supply system that requires the redundant electric power supply configuration is a vehicle capable of switching between manual driving and automated driving.

The generator 40 is equipment such as an alternator, for example, which is capable of outputting predetermined electric power. The electric power output by the generator 40 is supplied to the first battery 11, the first in-vehicle equipment 21, and so forth.

The first battery 11 is a secondary battery that is configured to be capable of charging and discharging, such as, for example, a lithium-ion battery, a nickel-metal hydride battery, or the like. The first battery 11 stores the electric power output by the generator 40, and releases (supplies) the electric power stored therein to the first in-vehicle equipment 21 and the DC-to-DC converter 30. As an example, the first battery 11 is provided as a main battery exclusively used for the vehicle to travel.

The second battery 12 is a secondary battery such as, for example, a lead-acid battery or a lithium-ion battery, which is configured so as to be capable of charging and discharging. The second battery 12 stores the electric power output by the generator 40 and the electric power of the first battery 11 via the DC-to-DC converter 30, and releases (supplies) the electric power stored therein to the second in-vehicle equipment 22 and so forth. This second battery 12 is provided redundantly, so that backup processing of the first battery 11 can be performed. As an example, the second battery 12 is provided so as to be capable of performing backup processing of maintaining provision of electric power supply to the second in-vehicle equipment 22 handling automated driving instead of the first battery 11, even when the first battery 11 fails during automated driving.

The first in-vehicle equipment 21 is a load that consumes electric power and that is installed in the vehicle. The first in-vehicle equipment 21 is configured to operate under electric power output by the generator 40 and/or electric power stored in the first battery 11.

The second in-vehicle equipment 22 is a load that consumes electric power and that is installed in the vehicle, and can be equipment that requires a more stable electric power supply than the first in-vehicle equipment 21 during automated driving of the vehicle. More specifically, the second in-vehicle equipment 22 is important equipment that requires electric power supply from the second battery 12 for a predetermined period of time and at a predetermined current even when the first battery 11 fails, thereby ensuring safe driving of the vehicle. The second in-vehicle equipment 22 can include equipment that performs an important function for safely performing evasive action of the vehicle in an emergency during automated driving, for example.

The DC-to-DC converter 30 is a voltage converter that is disposed between the first electric power line 71 and the second electric power line 72, converts the voltage of the input electric power to a predetermined voltage, and outputs the electric power of the predetermined voltage. This DC-to-DC converter 30 can be a step-up/step-down type DC-to-DC converter that has, for example, both of a step-down function of stepping down the voltage on a primary side (first battery 11 side) and outputting to a secondary side (second battery 12 side), and a step-up function of stepping up the voltage on the secondary side and outputting to the primary side.

The in-vehicle system 50 is a device for performing diagnosis of the second battery 12, and more specifically, the in-vehicle system 50 can perform determination regarding deterioration of the second battery 12. The in-vehicle system 50 can control the DC-to-DC converter 30 as appropriate, based on vehicle information (on/off state of ignition switch, state of manual driving/automated driving, and so forth) acquired from in-vehicle equipment that is omitted from illustration. The in-vehicle system 50 includes a discharge processing unit 51, an acquisition unit 52, a derivation unit 53, and a determination unit 54 in the configuration thereof.

When a request for performing diagnosis of the second battery 12 (diagnosis request) is generated in the vehicle, the discharge processing unit 51 implements “sensing discharge”, which is discharge processing for sensing deterioration of the second battery 12. A diagnosis request for the second battery 12 is typically generated by turning on the ignition switch, thereby starting a trip of the vehicle. This sensing discharge is performed by releasing a predetermined current from the second battery 12 toward the first in-vehicle equipment 21 and/or the second in-vehicle equipment 22.

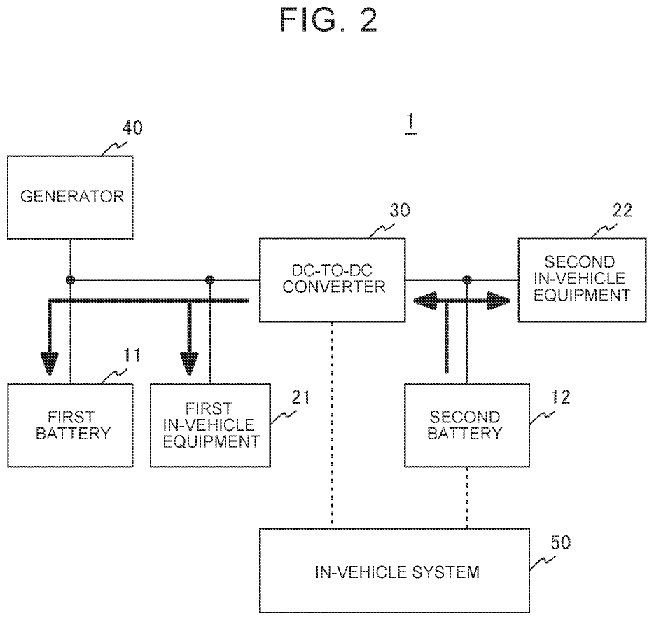

FIG. 2 illustrates an example of release paths of current (indicated by arrows) in the sensing discharge that the discharge processing unit 51 implements. As exemplified in FIG. 2, current is released from the second battery 12 to the first battery 11 and the first in-vehicle equipment 21 via the DC-to-DC converter 30, and release is performed directly from the second battery 12 to the second in-vehicle equipment 22.

When the results of the sensing discharge does not satisfy predetermined conditions (later-described “state determination conditions”), the discharge processing unit 51 performs controls such that the sensing discharge is repeatedly implemented not only on this trip but in the next trip as well (and further the following trip and thereafter) until results that satisfy the predetermined conditions are obtained, in principle. Requirements and so forth for repeatedly implementing will be described later.

The acquisition unit 52 acquires physical quantities indicating the state of the second battery 12, while the discharge processing unit 51 is implementing sensing discharge. The physical quantities indicating the state of the second battery 12 can be acquired from a detecting device (omitted from illustration), such as a sensor installed in the vehicle. Examples of the physical quantities indicating the state of the second battery 12 include voltage, current, temperature, and so forth. In the embodiment, the acquisition unit 52 acquires the current (released current) and voltage (output voltage) of the second battery 12 as the results of the sensing discharge implemented by the discharge processing unit 51.

The derivation unit 53 derives the internal resistance value of the second battery 12 based on the current and the voltage of the second battery 12, which are the results of the sensing discharge acquired by the acquisition unit 52. Derivation of the internal resistance value can be performed by a known technique, such as obtaining an inclination from a set of current and voltage. In the present embodiment, the derivation unit 53 derives the internal resistance value of the second battery 12 when results of the sensing discharge are obtained that satisfy the predetermined conditions.

The determination unit 54 determines the state of the second battery 12 based on the internal resistance value of the second battery 12, derived by the derivation unit 53. The state of the second battery 12 is determined to be either normal or deteriorated (abnormal), depending on whether the internal resistance value of the second battery 12 exceeds a predetermined threshold, for example. Also, the determination unit 54 can determine that the second battery 12 is deteriorated when a highly precise internal resistance value is not derived, such as when a state in which the results of the sensing discharge do not satisfy the predetermined conditions continues.

Part or all of the in-vehicle system 50 described above may typically be configured as an electronic control unit (ECU) such as a microcomputer or the like, including a processor, memory, an input/output interface, and so forth. This electronic control unit can realize part or all of the functions carried out by the discharge processing unit 51, the acquisition unit 52, the derivation unit 53, and the determination unit 54, which are described above, by the processor reading and executing programs stored in the memory.

Control

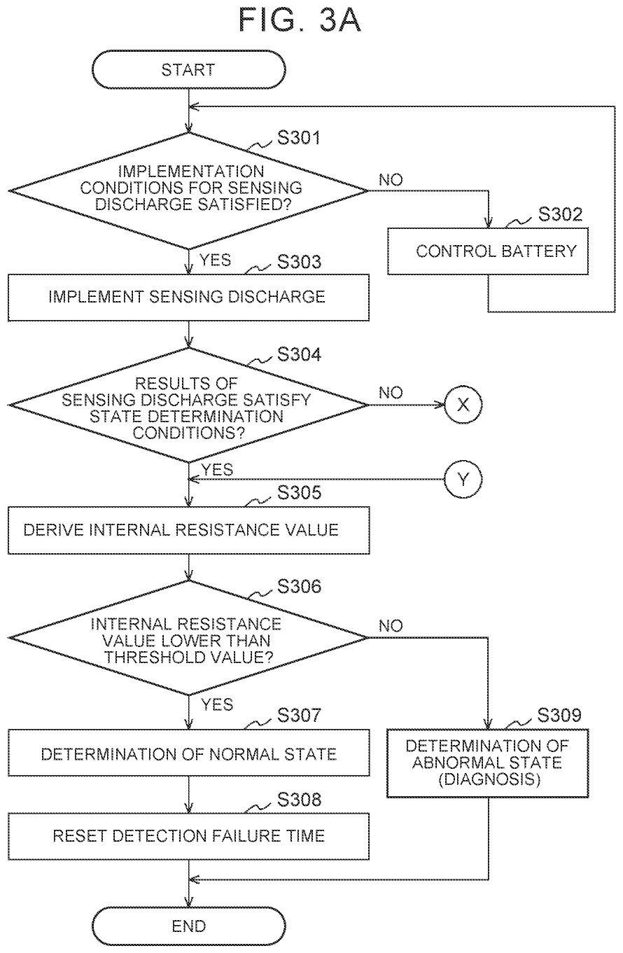

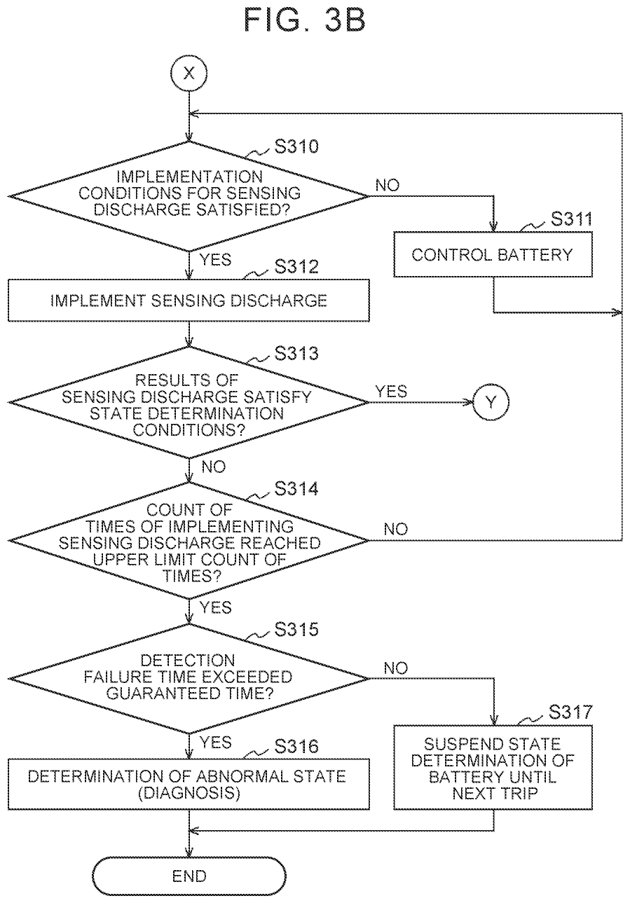

Next, control implemented by the in-vehicle system 50 according to the present embodiment will be described with reference to FIGS. 3A and 3B. FIGS. 3A and 3B are a flowchart that shows procedures of the state determination processing of the second battery 12, performed by the components of the in-vehicle system 50. The processing of FIG. 3A and the processing of FIG. 3B are connected by connectors X and Y.

The state determination processing of the second battery 12 exemplified in FIGS. 3A and 3B is started when the in-vehicle system 50 receives a request for sensing discharge from a host system or the like (omitted from illustration) of the vehicle, by the ignition switch of the vehicle being turned on and a trip being started, or the like, for example. When the state determination processing of the second battery 12 is started, a later-described count of times of implementing sensing discharge is reset to zero.

Step S301

The discharge processing unit 51 judges whether the second battery 12 satisfies conditions (hereinafter referred to as “implementation conditions”) necessary for performing the sensing discharge. The implementation conditions are conditions for suppressing an assumed state of the second battery 12 following sensing discharge from entering an unacceptable state, such as an over-discharged state. The implementation conditions are set based on the physical properties of the second battery 12 and so forth. The discharge processing unit 51 judges whether the second battery 12 satisfies the implementation conditions, based on the current state of the second battery 12 such as the state of charge (SOC) and temperature, and the physical quantities and so forth that vary due to the sensing discharge.

When the second battery 12 satisfies the implementation conditions of the sensing discharge (YES in step S301), the processing advances to step S303. On the other hand, when the second battery 12 does not satisfy the implementation conditions of the sensing discharge (NO in step S301), the processing advances to step S302.

Step S302

The discharge processing unit 51 controls the second battery 12. More specifically, the discharge processing unit 51 performs control and so forth, to charge the second battery 12 with the electric power output from the generator 40 and the electric power of the first battery 11 via the DC-to-DC converter 30 so that the second battery 12 satisfies the implementation conditions for the sensing discharge. After the second battery 12 is controlled, the processing advances to step S301.

Step S303

The discharge processing unit 51 implements sensing discharge (first time) of the second battery 12. This sensing discharge is implemented by applying a current of a predetermined value for a predetermined amount of time. The current value, amount of time, and so forth, of the sensing discharge are set in advance, based on the physical properties of the second battery 12, the performance of the DC-to-DC converter 30, and so forth. While this sensing discharge is being performed, the physical quantities of the second battery 12 are acquired by the acquisition unit 52 as appropriate. Also, when the sensing discharge is performed, the count of times of implementing the sensing discharge is incremented by one. When the sensing discharge of the second battery 12 is implemented, the processing advances to step S304.

Step S304

The discharge processing unit 51 determines whether the results of the sensing discharge satisfy the conditions necessary for determining the state of the second battery 12 (hereinafter referred to as “state determination conditions”). The state determination conditions are conditions for judging whether the current during the sensing discharge is widely fluctuating due to effects of the second in-vehicle equipment 22 or the like (whether unintended sensing discharge is being performed). The following two conditions can be exemplified for the state determination conditions.

State determination condition 1: That the average value of the discharged current of the second battery 12, measured a plurality of times during the sensing discharge, is within a first range

State determination condition 2: That the current value of the second battery 12 when the voltage of the second battery 12 is being measured following ending the sensing discharge is within a second range

The state determination condition 1 and the state determination condition 2 are based on an assumption of a scenario in which a current demand is occurring in the second in-vehicle equipment 22 of a magnitude so great that it cannot be accommodated by control of the DC-to-DC converter 30. In such a scenario, the derivation unit 53 cannot accurately derive the internal resistance value of the second battery 12 based on the physical quantities that the acquisition unit 52 acquires from the second battery 12 in the sensing discharge. Accordingly, determination is performed regrading whether the results of the sensing discharge satisfy the state determination condition 1 or the state determination condition 2 described above. Note that the first range and the second range used for each state determination condition are set to predetermined ranges that are unacceptable as measurement error.

When the results of the sensing discharge satisfy the state determination conditions (YES in step S304), judgement is made that the sensing discharge has been implemented as intended, and the processing advances to step S305. On the other hand, when the results of the sensing discharge do not satisfy the state determination conditions (NO in step S304), judgement is made that the sensing discharge has not been implemented as intended, and the processing advances to step S310.

Step S305

The derivation unit 53 derives the internal resistance value of the second battery 12 based on the results of the sensing discharge. This internal resistance value can be derived using a known method based on the physical quantities (voltage and current) acquired by the acquisition unit 52 from the second battery 12 as a result of the sensing discharge. After the internal resistance value of the second battery 12 is derived, the processing advances to step S306.

Step S306

The determination unit 54 determines whether the internal resistance value of the second battery 12 is lower than a predetermined threshold. This determination processing is performed to decide whether the second battery 12 is deteriorated. Accordingly, the predetermined threshold value can be set to an optional value, of which the upper limit is the greatest value of the internal resistance value at which the second battery 12 can be judged to be normal.

When the internal resistance value of the second battery 12 is lower than the predetermined threshold value (YES in step S306), the processing advances to step S307. On the other hand, when the internal resistance value of the second battery 12 is not lower than the predetermined threshold value (NO in step S306), the processing advances to step S309.

Step S307

The determination unit 54 determines that the second battery 12 is normal (determination of normal state). When determining that the second battery 12 is normal, the processing advances to step S308.

Step S308

The determination unit 54 resets detection failure time to zero, and starts timing anew. This detection failure time is the amount of time that has elapsed since the determination unit 54 determined that the second battery 12 is normal the last time, and is used for the purpose of setting a time limit for processing when state determination of the second battery 12 is not performed over a long period of time. Accordingly, the detection failure time is set to, for example, an amount of time over which the determination results that the second battery 12 is normal can assumed to be maintained (hereinafter referred to as “guaranteed time”). When the detection failure time is reset, the state determination processing of the second battery 12 for the current trip ends.

Step S309

The determination unit 54 determines that the second battery 12 is deteriorated (determination of abnormal state). Also, the determination unit 54 issues a predetermined diagnosis based on this determination of abnormal state. Upon determining that the second battery 12 is deteriorated, the state determination processing of the second battery 12 for the current trip ends.

Processing following the discharge processing unit 51 judging that the results of the sensing discharge do not satisfy the state determination conditions (NO in step S304) will be described below. In the processing following step S310, which will be described below, sensing discharge is implemented again a second time, or a third time or more (retry processing).

Step S310

The discharge processing unit 51 judges whether the second battery 12 satisfies the implementation conditions for sensing discharge. This judgment is the same as the judgment made in step S301 above. When the second battery 12 satisfies the implementation conditions for sensing discharge (YES in step S310), the processing advances to step S312, and when the second battery 12 does not satisfy the implementation conditions for sensing discharge (NO in step S310), the processing advances to step S311.

Step S311

The discharge processing unit 51 controls the second battery 12 such that the second battery 12 satisfies the implementation conditions for sensing discharge. This control is the same as the control performed in step S302 above. Once the second battery 12 is controlled, the processing advances to step S310.

Step S312

The discharge processing unit 51 implements sensing discharge of the second battery 12. This sensing discharge is the same as the sensing discharge performed in step S303 above. Also, the count of times of sensing discharge being implemented is incremented by one. Upon implementing sensing discharge of the second battery 12, the processing advances to step S313.

Step S313

The discharge processing unit 51 judges whether the results of the sensing discharge satisfy the state determination conditions. This judgment is the same as the judgment made in step S304 above. When the results of the sensing discharge satisfy the state determination conditions (YES in step S313), judgement is made that the sensing discharge has been implemented as intended, and the processing advances to step S305. When the results of the sensing discharge do not satisfy the state determination conditions (NO in step S313), judgement is made that the sensing discharge has not been implemented as intended, and the processing advances to step S314.

Step S314

The discharge processing unit 51 judges whether the count of times of implementing sensing discharge has reached a predetermined upper limit count of times. This judgement is made to curb useless repetition of sensing discharge that cannot be used for state determination. The count of times of implementation can be the total count of times of sensing discharge performed in step S303 above and sensing discharge performed in step S312 above. Also, the upper limit count of times is optionally set based on the load placed on the in-vehicle system 50, the physical properties of the second battery 12, and so forth.

When the count of times of implementing sensing discharge has reached the upper limit count of times (YES in step S314), the processing advances to step S315. On the other hand, when the count of times of implementing sensing discharge has not yet reached the upper limit count of times (NO in step S314), the processing advances to step S310, to further implement sensing discharge.

Step S315

The determination unit 54 judges whether the detection failure time, which is the amount of time that has elapsed since the previous determination that the second battery 12 is normal, has exceeded the guaranteed time over which the determination of normal state for the second battery 12 can assumed to be maintained. This judgment is made to end the determination of normal state results, when a state continues in which state determination of the second battery 12 cannot be performed, to the extent that it is difficult to maintain the previous determination of normal state results. The guaranteed time can be optionally set based on dark current of the second in-vehicle equipment 22, the physical properties of the second battery 12, and so forth.

When the detection failure time exceeds the guaranteed time (YES in step S315), the processing advances to step S316. On the other hand, when the detection failure time does not exceed the guaranteed time (NO in step S315), the processing advances to step S317.

Step S316

The determination unit 54 determines that the second battery 12 is deteriorated (determination of abnormal state). Also, the determination unit 54 issues a predetermined diagnosis based on this determination of abnormal state. Upon determining that the second battery 12 is deteriorated, the state determination processing of the second battery 12 for the current trip ends.

Step S317

The determination unit 54 suspends determination of the state of the second battery 12 until the next trip. That is to say, during the current trip, the determination unit 54 maintains the previous determination results that the second battery 12 is normal (the results determined in step S307), and leaves determination of the current state of the second battery 12 to the next trip. The determination of normal state is maintained, and accordingly use of the second battery 12 by the vehicle is permitted. When the state determination of the second battery 12 is suspended until the next trip, the state determination processing of the second battery 12 ends for the current trip.

Modification 1

In the retry processing exemplified in the flowchart in FIG. 3B, when the results of the sensing discharge do not satisfy the state determination conditions, sensing discharge is repeatedly implemented until the count of times of implementing sensing discharge reaches the upper limit count of times in the same trip. (steps S310 to S314). In Modification 1, the following retry processing a1 to a6 is performed instead of this retry processing.

In a1, when the results of sensing discharge do not satisfy the state determination conditions, sensing discharge is repeatedly implemented until the count of times of implementing sensing discharge in the same trip reaches a predetermined intermediate count of times (set to less than the upper limit count of times). To a2

In a2, judgement is made regarding whether the detection failure time exceeds the guaranteed time. To a3 or a4
In a3, when the detection failure time exceeds the guaranteed time, sensing discharge is repeatedly implemented until the count of times of implementing sensing discharge reaches the upper limit count of times in the same trip. To a5
In a4, when the detection failure time does not exceed the guaranteed time, sensing discharge is implemented in the next trip.
In a5, judgement is made regarding whether the detection failure time exceeds the guaranteed time. To a4 or a6
In a6, when the detection failure time exceeds the guaranteed time, determination is made that the second battery 12 is deteriorated.

Modification 2

In the retry processing exemplified in the flowchart in FIG. 3B, when the results of the sensing discharge do not satisfy the state determination conditions, sensing discharge is repeatedly implemented until the count of times of implementing sensing discharge reaches the upper limit count of times in the same trip. (steps S310 to S314). In Modification 2, the following retry processing b1 to b3 is performed instead of this retry processing.

In b1, when the results of the sensing discharge do not satisfy the state determination conditions, judgement is made regarding whether the detection failure time exceeds the guaranteed time. To b2 or b3

In b2, when the detection failure time exceeds the guaranteed time, determination is made that the second battery 12 is deteriorated.
In b3, when the detection failure time does not exceed the guaranteed time, sensing discharge is implemented in the next trip.
That is to say, Modification 2 is processing in which retry of sensing discharge is not performed in the same trip (processing in which steps S310 to S313 are omitted from the flowchart in FIG. 3B).

Operations and Effects

As described above, according to the in-vehicle system 50 according to an embodiment of the present disclosure, when results of sensing discharge implemented at first do not satisfy state determination conditions, and diagnosis of the second battery 12 cannot be performed with high precision, sensing discharge is repeatedly implemented until the results of sensing discharge satisfy the state determination conditions (retry processing). According to this in-vehicle system 50, when the results of sensing discharge still do not satisfy the state determination conditions even though retry processing is performed the upper limit count of times within the same trip, whether to maintain the determination of normal state or to make a determination of abnormal state is decided based on whether the elapsed time from the previous point in time when the second battery 12 was determined to be normal is within the guaranteed time, regardless of the internal resistance value of the second battery 12.

According to this processing, state determination processing of the second battery 12, maintained over a plurality of trips, can be implemented. For this reason, even when the timing of electric power consumption by the second in-vehicle equipment 22 in this trip is unsuitable (e.g., the timing coincides with sensing discharge), and sensing discharge of the second battery 12 cannot be implemented as intended, for example, sensing discharge can be anticipated to be implemented as intended on the next trip. Accordingly, precision of diagnosis of the second battery 12 can be improved.

Although an embodiment of the present disclosure has been described above, the present disclosure can be understood as being not only an in-vehicle system, but also as a battery diagnosis method executed by an in-vehicle system including a processor, memory, and so forth, a program for executing this battery diagnosis method, a computer-readable non-transitory storage medium that stores the program, and a vehicle equipped with the in-vehicle system.

The in-vehicle system and so forth of the present disclosure can be used for diagnosing a battery installed in a vehicle.

What is claimed is:

1. An in-vehicle system that diagnoses a battery installed in a vehicle, the in-vehicle system comprising one or more processors configured to:
control the battery to implement sensing discharge that is discharge processing for sensing deterioration of the battery;
determine whether a result of the sensing discharge satisfies a predetermined condition;
control the battery to implement the sensing discharge again when determination is made that the result of the sensing discharge does not satisfy the predetermined condition;
derive an internal resistance value of the battery based on the result of the sensing discharge when determination is made that the result of the sensing discharge satisfies the predetermined condition; and
perform deterioration determination of the battery based on the internal resistance value.

2. The in-vehicle system according to claim 1, wherein the one or more processors are configured to control the battery such that the sensing discharge is not implemented until a next trip, when determination is made that the result of the sensing discharge does not satisfy the predetermined condition, and a count of times of the sensing discharge implemented in a current trip of the vehicle reaches a predetermined upper limit count of times.

3. The in-vehicle system according to claim 2, wherein the one or more processors are configured to determine that the battery is deteriorated, when determination is made that the result of the sensing discharge does not satisfy the predetermined condition, and the count of times of the sensing discharge implemented in the current trip reaches the predetermined upper limit count of times, and also when a predetermined amount of time or more has elapsed since deterioration determination of the battery was performed a previous time.

4. The in-vehicle system according to claim 1, wherein the predetermined condition is that an average value of a discharge current, during implementation of the sensing discharge, is within a predetermined first range.

5. The in-vehicle system according to claim 1, wherein the predetermined condition is that a current value, when measuring voltage following implementation of the sensing discharge, is within a predetermined second range.

6. The in-vehicle system according to claim 1, wherein the one or more processors are configured to control the battery such that the sensing discharge is implemented in response to a request output by turning on an ignition switch that starts a trip of the vehicle.

7. The in-vehicle system according to claim 6, wherein:
the one or more processors are configured to, upon receiving the request, determine whether the battery satisfies a predetermined implementation condition; and
the predetermined implementation condition here is a condition such that the battery does not enter an over-discharged state following the sensing discharge.

8. The in-vehicle system according to claim 2, wherein the one or more processors are further configured to:
determine whether the count of times of the sensing discharge implemented in the current trip has reached a predetermined intermediate count of times that is a fewer count of times than the predetermined upper limit count of times;
determine whether elapsed time since deterioration determination of the battery was performed a previous time exceeds a predetermined amount of time, when determination is made that the result of the sensing discharge does not satisfy the predetermined condition, and determination is made that the count of times of the sensing discharge implemented in the current trip has reached the predetermined intermediate count of times;
control the battery to implement the sensing discharge again, when determination is made that the elapsed time exceeds the predetermined amount of time; and
control the battery not to implement the sensing discharge until the next trip, when determination is made that the elapsed time does not exceed the predetermined amount of time.

9. A battery diagnostic method executed by one or more processors of an in-vehicle system that diagnoses a battery installed in a vehicle, the battery diagnostic method comprising:
controlling the battery to implement sensing discharge that is discharge processing for sensing deterioration of the battery;
determining whether a result of the sensing discharge satisfies a predetermined condition;
controlling the battery to implement the sensing discharge again when determination is made that the result of the sensing discharge does not satisfy the predetermined condition;
deriving an internal resistance value of the battery based on the result of the sensing discharge when determination is made that the result of the sensing discharge satisfies the predetermined condition; and
performing deterioration determination of the battery based on the internal resistance value.

10. A vehicle equipped with the in-vehicle system according to claim 1.
